(19) United States
(12) Patent Application Publication
(10) Pub. No.: US 2008/0111131 A1
(43) Pub. Date: May 15, 2008

(54) Organic thin film transistor, method of fabricating the same, and display device including the same

(76) Inventor: Nam-Choul Yang, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/979,887

(22) Filed: Nov. 9, 2007

(30) Foreign Application Priority Data
Nov. 10, 2006 (KR) 10-2006-0111182
Nov. 10, 2006 (KR) 10-2006-0111183

(51) Int. Cl. H01L 51/10

(52) U.S. Cl. 257/40; 257/E51.005

(57) ABSTRACT

An organic thin film transistor (OTFT) includes an organic semiconductor layer on a substrate, source/drain electrodes spaced apart from each other on the substrate, a mixed layer between the source/drain electrodes and the organic semiconductor layer, the mixed layer including an organic material and a metal oxide or metal salt, and a gate electrode.

### BACKGROUND OF THE INVENTION

1. Field of the Invention

Embodiments of the present invention relate to an organic thin film transistor (OTFT), a method of fabricating the same, and a display device including the same. More particularly, embodiments of the present invention relate to an OTFT having enhanced hole/electron injection properties.

2. Description of the Related Art

In general, organic thin film transistors (OTFTs) refer to thin film transistors having an organic layer as a semiconductor layer instead of a silicon layer. The organic semiconductor layer may include a low molecular weight organic compound, e.g., oligothiophene, pentacene, and so forth, or a polymer, e.g., polythiophene, and so forth.

The conventional OTFT may operate, e.g., as a driving device of a display device. When the OTFT is employed in a conventional display device, the display device may include at least two OTFTs, e.g., a switching OTFT and a driving OTFT, a capacitor, a plurality of electrodes and a light source on a substrate, e.g., a flexible substrate. The conventional OTFT may include a gate electrode, source/drain electrodes, a gate insulating layer between the gate electrode and the source/drain electrodes, and an organic semiconductor layer on the source/drain electrodes.

However, disposing the organic semiconductor layer directly on the source/drain electrodes may increase a resistance therebetween, i.e., impede formation of an ohmic contact, due to differences in Fermi energies of the organic semiconductor layer and the source/drain electrodes. For example, manufacturing at low temperatures, e.g., due to thermal sensitivity of a plastic flexible substrate, may limit a doping concentration in the organic semiconductor layer, consequently causing a reduced flow of holes/electrons between the source/drain electrodes and the organic semiconductor layer due to a high resistance therebetween. Accordingly, there exists a need for an OTFT having a reduced resistance between the organic semiconductor layer and the source/drain electrodes in order to enhance hole/electron injection properties therebetween.

### SUMMARY OF THE INVENTION

Embodiments of the present invention are therefore directed to an organic thin film transistor (OTFT), a method of fabricating the same, and a display device including the same, which substantially overcome one or more of the disadvantages of the related art.

It is therefore a feature of an embodiment of the present invention to provide an OTFT having a structure capable of reducing resistance between the organic semiconductor layer and the source/drain electrodes.

It is therefore another feature of an embodiment of the present invention to provide a display device including an OTFT with enhanced holes/electrons injection properties.

It is yet another feature of an embodiment of the present invention to provide a method of fabricating an OTFT having a structure capable of reducing resistance between the organic semiconductor layer and the source/drain electrodes.

At least one of the above and other features and advantages of the present invention may be realized by providing an OTFT including a substrate, a gate electrode disposed on the substrate, a gate insulating layer disposed on the entire surface of the substrate including the gate electrode, source and drain electrodes spaced apart from each other on some regions of the gate insulating layer, a mixed layer disposed on the source and drain electrodes and including an organic material and a metal oxide, and a P-type organic semiconductor layer disposed on the substrate including the mixed layer.

The organic semiconductor layer may be a P-type organic semiconductor layer. Accordingly, the organic material of the mixed layer may be a triarylamine-based material or an acene-based material. The acene-based material may be anthracene, tetracene, pentacene, perylene, or coronene. The metal oxide may be molybdenum oxide (MoO₃), vanadium oxide (V₂O₅), tungsten oxide (WO₃) or nickel oxide (NiO). The metal oxide may be present in the mixed layer at an amount of about 25% to about 80% based on a total weight of the mixed layer.

At least one of the above and other features and advantages of the present invention may be also realized by providing an OTFT including a substrate, a gate electrode disposed on the substrate, a gate insulating layer disposed on the entire surface of the substrate including the gate electrode, source and drain electrodes spaced apart from each other on some regions of the gate insulating layer, a mixed layer disposed on the source and drain electrodes and including an organic material and a metal salt, and an N-type organic semiconductor layer disposed on the substrate including the mixed layer.

The organic semiconductor layer may be a N-type organic semiconductor layer. Accordingly, the organic material of the mixed layer may be comprised of a material selected from the group consisting of acene, fully fluorinated acene, partially fluorinated acene, partially fluorinated oligothiophene, fullerene, fullerene having substituent, fully fluorinated phthalocyanine, partially fluorinated phthalocyanine, perylene tetracarboxylic diimide, perylene tetracarboxylic dianhydride, naphthalene tetracarboxylic diimide, and naphthalene tetracarboxylic dianhydride. The acene-based material may be anthracene, tetracene, pentacene, perylene, coronene, or a fluorinated acene. The metal salt may contain an alkali metal or an alkaline-earth metal. The metal salt may be cesium chloride (CsCl), cesium fluoride (CsF) or cesium carbonate (Cs₂CO₃). The amount of the metal salt in the mixed layer may be about 5% to about 50% based on a total weight of the mixed layer.

At least one of the above and other features and advantages of the present invention may be also realized by providing a light emitting display device including a substrate, a gate electrode disposed on the substrate, a gate insulating layer disposed on the entire surface of the substrate including the gate electrode, source and drain electrodes spaced apart from each other on some regions of the gate insulating layer, a mixed layer disposed on the source and drain electrodes, and including an organic material and a metal oxide, a P-type organic semiconductor layer disposed on the substrate including the mixed layer, a passivation layer disposed on the P-type organic semiconductor layer, a first electrode connected to the source and drain electrodes, a pixel defining layer exposing a portion of the first electrode, an organic layer disposed on the first electrode, and including an organic emitting layer, and a second electrode disposed on the organic layer.

At least one of the above and other features and advantages of the present invention may be also realized by providing a light emitting display device including a substrate, a gate electrode disposed on the substrate, a gate insulating layer disposed on the entire surface of the substrate including the gate electrode, source and drain electrodes spaced apart from each other on some regions of the gate insulating layer, a mixed layer disposed on the source and drain electrodes, and including an organic material and a metal salt, an N-type organic semiconductor layer disposed on the substrate including the mixed layer, a passivation layer disposed on the N-type organic semiconductor layer, a first electrode connected to the source and drain electrodes, a pixel defining layer exposing a portion of the first electrode, an organic layer disposed on the first electrode, and including an organic emitting layer, and a second electrode disposed on the organic layer.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of an organic thin film transistor (OTFT) according to an exemplary embodiment of the present invention;

FIG. 2 illustrates a cross-sectional view of an OTFT according to another exemplary embodiment of the present invention;

FIG. 3 illustrates a cross-sectional view of a display device including an OTFT according to an exemplary embodiment of the present invention; and

FIG. 4 illustrates a cross-sectional view of a display device including an OTFT according to another exemplary embodiment of the present invention.

### DETAILED DESCRIPTION OF THE INVENTION

Korean Patent Application Nos. 10-2006-111182 and 10-2006-111183, both filed on Nov. 10, 2006, in the Korean Intellectual Property Office, and entitled: “Organic Thin Film Transistor, Method of Fabricating the Same, and Organic Light Emitting Display Device Including the Same,” are incorporated by reference herein in their entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

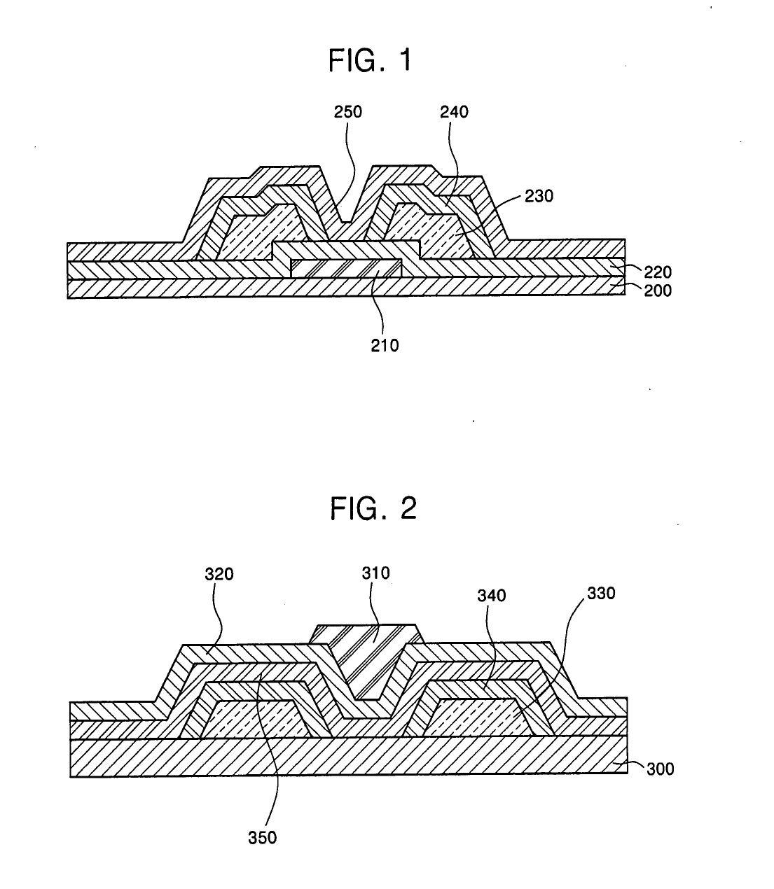

An exemplary embodiment of an organic thin film transistor (OTFT) according to the present invention will now be described more fully with reference to FIG. 1. As illustrated in FIG. 1, an OTFT may include a substrate 200, a gate electrode 210, a gate insulating layer 220 on the substrate 200, source/drain electrodes 230, an organic semiconductor layer 250, and a mixed layer 240 between the organic semiconductor layer 250 and the source/drain electrodes 230.

The substrate 200 of the OTFT according to an embodiment of the present invention may be formed of a transparent material, e.g., glass, to facilitate transmission of ultraviolet (UV) light therethrough. Alternatively, the substrate 200 may be formed of silicon or plastic, e.g., polyethersulphone (PES), polyacrylate, polyetherimide, polyethylene naphthalate (PEN), polyethylene terephthalate (PET), polyphenylene sulfide (PPS), polyarylate, polyimide, polycarbonate (PC), cellulose tri acetate (TAC), cellulose acetate propionate (CAP), and so forth.

The gate electrode 210 of the OTFT according to an embodiment of the present invention may be formed of a conductive material, e.g., an aluminum (Al), an Al-alloy, molybdenum (Mo), a Mo-alloy, and so forth.

The gate insulating layer 220 of the OTFT according to an embodiment of the present invention may be formed on the substrate 200 and in communication with the gate electrode 210, such that the gate electrode 210 may be positioned between the substrate 200 and the gate insulating layer 220, as illustrated in FIG. 1. The gate insulating layer 220 may be formed of a single layer, e.g., a single organic insulating layer or a single inorganic insulating layer, a multi-layer structure, e.g., a plurality of organic insulating layers or a plurality of inorganic insulating layers, or an organic-inorganic hybrid structure. An inorganic material employed in the gate insulating layer 220 may include, e.g., silicon oxide (SiOx), silicon nitride (SiNx), aluminum oxide (Al2O3), tantalum oxide (Ta2O5), barium strontium titanate (BST), lead zirconium titanate (PZT), and so forth. An organic material employed in the gate insulating layer 220 may include polyacryl, e.g., polymethyl methacrylate (PMMA), polystyrene (PS), a phenol-based polymer, a polyimide, a polyaryl-ether, a polyamide, a fluorine-based polymer, a p-xylene-based polymer, a polyvinylalcohol-based polymer, parylene, and so forth.

The source/drain electrodes 230 of the OTFT according to an embodiment of the present invention may be spaced apart from each other on the gate insulating layer 220. The source/drain electrodes 230 may include a single metal layer, e.g., aluminum (Al), silver (Ag), molybdenum (Mo), gold (Au), platinum (Pt), palladium (Pd), nickel (Ni), indium-tin-oxide (ITO), indium-zinc-oxide (IZO), or an alloy thereof. Alternatively, the source/drain electrodes 230 may be formed of a plurality of metal layers including at least one adhesion metal layer, e.g., titanium (Ti), chromium (Cr), aluminum (Al), and so forth.

The organic semiconductor layer 250 of the OTFT according to an embodiment of the present invention may be formed on the substrate 200. More specifically, the organic semiconductor layer 250 may be formed as a P-type organic semiconductor layer or as a N-type organic semiconductor layer on the entire surface of the substrate 200 in order to cover the mixed layer 240, as will be discussed in detail below. Alternatively, P-type or N-type impurities may be doped only into source/drain regions of the OTFT.

When the organic semiconductor layer 250 is a P-type organic semiconductor layer, it may include an acene-based compound, e.g., pentacene, perylene, tetracene, anthracene, perylene, coronene, and so forth, poly-thienylenevinylene, poly-3-hexylthiophene, α-hexathienylene, naphthalene, α-6-thiophene, α-4-thiophene, rubrene, polythiophene, polyparaphenylenevinylene, polyparaphenylene, polyfluorene, polythiophenevinylene, polythiophene-heterocyclic aromatic copolymer, triarylamine, and derivatives thereof. Alternatively, when the organic semiconductor layer 250 is an N-type organic semiconductor layer, it may include an acene-based compound, a fully fluorinated acene, a partially fluorinated acene, a partially fluorinated oligothiophene, a fullerene-based compound, a fluorinated phthalocyanine, e.g., a fully fluorinated phthalocyanine and a partially fluorinated phthalocyanine, perylene tetracarboxylic diimide, perylene tetracarboxylic dianhydride, naphthalene tetracarboxylic diimide, and naphthalene tetracarboxylic dianhydride.

The mixed layer 240 of the OTFT according to an embodiment of the present invention may be formed on the source/drain electrodes 230 by co-deposition to a thickness of about 10 angstroms to about 1000 angstroms. A thickness of the mixed layer 240 below about 10 angstroms may be insufficient to enhance hole/electron injection efficiency, and a thickness above about 1000 angstroms may unnecessarily increase costs and process time. The mixed layer 240 may be disposed between the organic semiconductor layer 250 and the source/drain electrodes 230 to minimize or eliminate contact therebetween.

Without intending to be bound by theory, it is believed that disposing the mixed layer 240 between the organic semiconductor layer 250 and the source/drain electrodes 230 may position the mixed layer 240 between a highest occupied molecular orbital (HOMO) level of the organic semiconductor layer 250 and a HOMO level of the source/drain electrodes 230 to minimize resistance therebetween. In other words, even though a numerical difference between the Fermi level of the source/drain electrodes 230 and the HOMO level of the organic semiconductor layer 250 may provide a large value that is unchanged with respect to a conventional OTFT having no mixed layer, a HOMO level of the mixed layer 240 positioned between the source/drain electrodes 230 and the organic semiconductor layer 250 may minimize the large value, i.e., energy difference between the Fermi level of the source/drain electrodes 230 and the HOMO level of the organic semiconductor layer 250. The reduced energy difference may reduce overall resistance between the source/drain electrodes 230 and the organic semiconductor layer 250, consequently increasing transport of holes or electrons into the P-type or N-type organic semiconductor layer 250, respectively, through the mixed layer 240.

The mixed layer 240 may be formed of a mixture containing an organic material and a metal oxide or metal salt. More specifically, the composition of the mixed layer 240 may be determined with respect to a material employed to form the organic semiconductor layer 250, i.e., whether the organic semiconductor layer 250 is formed as a P-type organic semiconductor layer or as a N-type organic semiconductor layer. In detail, if the organic semiconductor layer 250 is formed as a P-type layer, the mixed layer 240 may include a P-type organic compound and a metal oxide. Alternatively, if the organic semiconductor layer 250 is formed as a N-type layer, the mixed layer 240 may include a N-type organic compound and a metal salt.

In further detail, when the organic semiconductor layer 250 is formed as a P-type semiconductor layer, the mixed layer 240 may include a metal oxide, e.g., molybdenum oxide (MoO₃), vanadium oxide (V₂O₅), tungsten oxide (WO₃), nickel oxide (NiO), and so forth, in an amount of about 25% to about 80% by weight of the mixed layer 240. If the amount of metal oxide is below about 25% by weight of the mixed layer 240, resistance between the source/drain electrodes 230 and the organic semiconductor layer 250 may be reduced insufficiently. On the other hand, if the amount of metal oxide is above about 80% by weight of the mixed layer 240, a surface roughness of the mixed layer 240 may be too high, thereby reducing reliability of the OTFT. The P-type organic material employed in the mixed layer 240 may be any type of material capable of transporting organic charges. The P-type organic material may be identical to the P-type organic material employed to form the organic semiconductor layer 250, e.g., an acene-based material or a material containing triarylamine.

When the organic semiconductor layer 250 is formed as a N-type semiconductor layer, the mixed layer 240 may include a metal salt, e.g., cesium chloride (CsCl), cesium fluoride (CsF), cesium carbonate (Cs₂CO₃), and so forth, in an amount of about 5% to about 50% by weight of the mixed layer 240. The metal salt may include an alkali metal or an alkaline earth metal. If the amount of metal salt is below about 5% by weight of the mixed layer 240, resistance between the source/drain electrodes 230 and the organic semiconductor layer 250 may be reduced insufficiently. On the other hand, if the amount of metal salt is above about 50% by weight of the mixed layer 240, electron injection efficiency may be lower as compared to a comparable mixed layer, i.e., a layer having a substantially similar composition, including no metal salt. The N-type organic material employed in the mixed layer 240 may be identical to the N-type organic material employed to form the organic semiconductor layer 250.

According to another exemplary embodiment of an OTFT illustrated in FIG. 2, the OTFT may include a substrate 300, source/drain electrodes 330 on the substrate 300, an organic semiconductor layer 350 on the substrate 300, a mixed layer 340 between the organic semiconductor layer 350 and the source/drain electrodes 330, a gate electrode 310 on the organic semiconductor layer 350, and a gate insulating layer 320 between the organic semiconductor layer 350 and the gate electrode 310. The composition and structure of the elements of the OTFT described with respect to FIG. 2 are identical to the composition and structure of respective elements of the OTFT described previously with respect to FIG. 1, with the exception of forming the gate electrode 310 on the organic semiconductor layer 350, and accordingly, their detailed description will not be repeated herein. In this respect, it should be noted that first digits of reference numerals, i.e., ‘2’ and ‘3’, are employed to distinguish embodiments and not elements, and therefore, reference numerals having identical last two digits refer to similar elements.

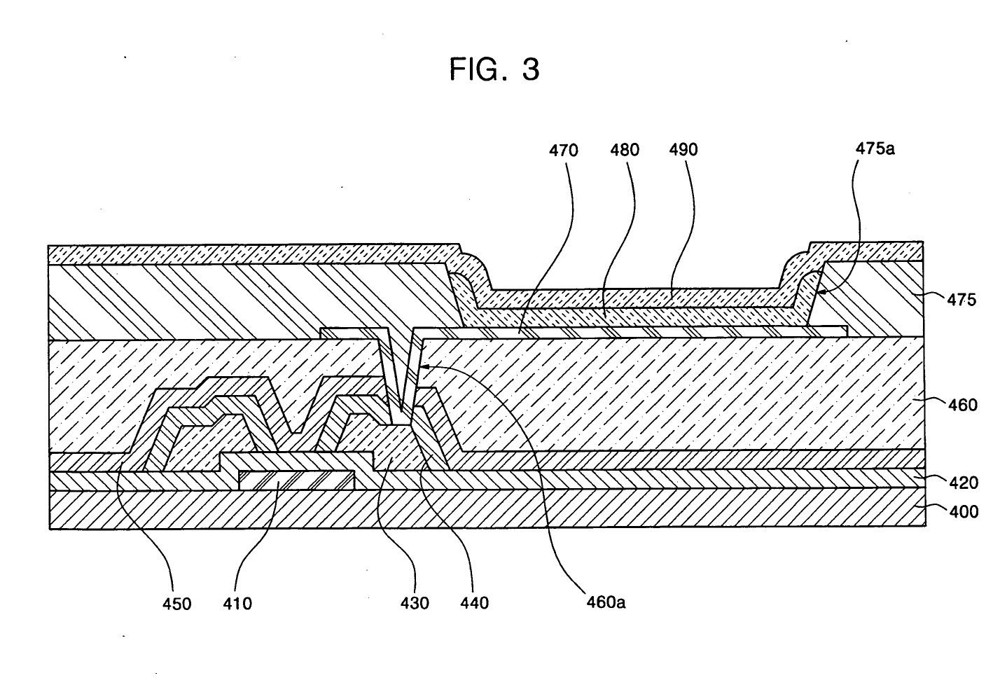

According to yet another exemplary embodiment of the present invention, a display device, e.g., an organic light emitting display device, may be formed to include the OTFT described previously with respect to FIG. 1. The flat display device may include, as illustrated in FIG. 3, an OTFT, a passivation layer 460 on the OTFT, a pixel defining layer 475, first and second electrodes 470 and 490 on the passivation layer 460, and a light emitting layer 480 between the first and second electrodes 470 and 490. The OTFT may include a substrate 400, a gate electrode 410, a gate insulating layer 420, source/drain electrodes 430, a mixed layer 440, and an organic semiconductor layer 450.

More specifically, the substrate 400 may be prepared, and the gate electrode 410 may be formed thereon. The gate insulating layer 420 may be deposited to cover the entire surface of the substrate 400 including the gate electrode 410. The source/drain electrodes 430 may be spaced apart from each other on the gate insulating layer 420. The mixed layer 440 may be formed on the source/drain electrodes 423 by a co-deposition method. The organic semiconductor layer 450 may be formed on the entire surface of the substrate 400 including the mixed layer 440, such that the mixed layer 440 may be positioned between the source/drain electrodes 430 and the organic semiconductor layer 450 to minimize or to prevent contact therebetween, to complete formation of the OTFT illustrated in FIG. 3. The OTFT employed in the display device described with respect to FIG. 3 may be similar to the OTFT described previously with respect to FIG. 1, and therefore, detailed description of its respective elements will not be repeated herein. In this respect, it should be noted that first digits of reference numerals, i.e., ‘2’ and ‘4’, are employed to distinguish embodiments and not elements, and therefore, reference numerals having identical last two digits refer to similar elements.

The passivation layer 460 of the display device according to an embodiment of the present invention may be deposited on the substrate 400 above the OTFT. The passivation layer 460 may be formed on the entire surface of the substrate including the organic semiconductor layer 450 of SiNx, SiOx, or a multiple layer thereof. If the display device is a top light emitting display device, a planarization layer (not shown) may be deposited on the passivation layer 460. An upper surface of the passivation layer 460 may be etched to form a via hole 460a therethrough in order to expose an upper surface of the source/drain electrode 430.

The first electrode 470 of the flat panel display according to an embodiment of the present invention may be formed on the passivation layer 460 and in communication with the source/drain electrode 430 of the OTFT through the via hole 460a. The first electrode 470 may be formed of a transparent conductive material having a low work function, e.g., ITO and IZO. The first electrode 470 may also include at least one reflective layer of a non-transparent metal, e.g., Al, Ag, or an alloy thereof, below the conductive material in order to reflect emitted light in an upward direction.

The pixel defining layer 475 of the display device according to an embodiment of the present invention may be deposited and patterned on the first electrode 470 to form an opening 475a to expose an upper surface of the first electrode 470. The pixel defining layer 475 may be formed of benzo-cyclobutene, polyimide, polyamide, acrylic resin, silicon-on-glass (SOG), and like materials.

The light emitting layer 480 of the display device according to an embodiment of the present invention may be formed on the first electrode 470 of a light emitting material, e.g., organic light emitting material, by inkjet printing, deposition, laser-induced thermal imaging, and so forth. The organic layer 480 may have a single layer structure or a multi-layer structure, e.g., a hole injection layer, a hole transport layer, an electron injection layer, an electron transport layer, and/or a hole blocking layer.

The second electrode 490 of the display device according to an embodiment of the present invention may be formed on the entire surface of the substrate 400 including the organic layer 480. The second electrode 490 may be formed of silver (Ag), aluminum (Al), calcium (Ca), magnesium (Mg), or an alloy thereof.

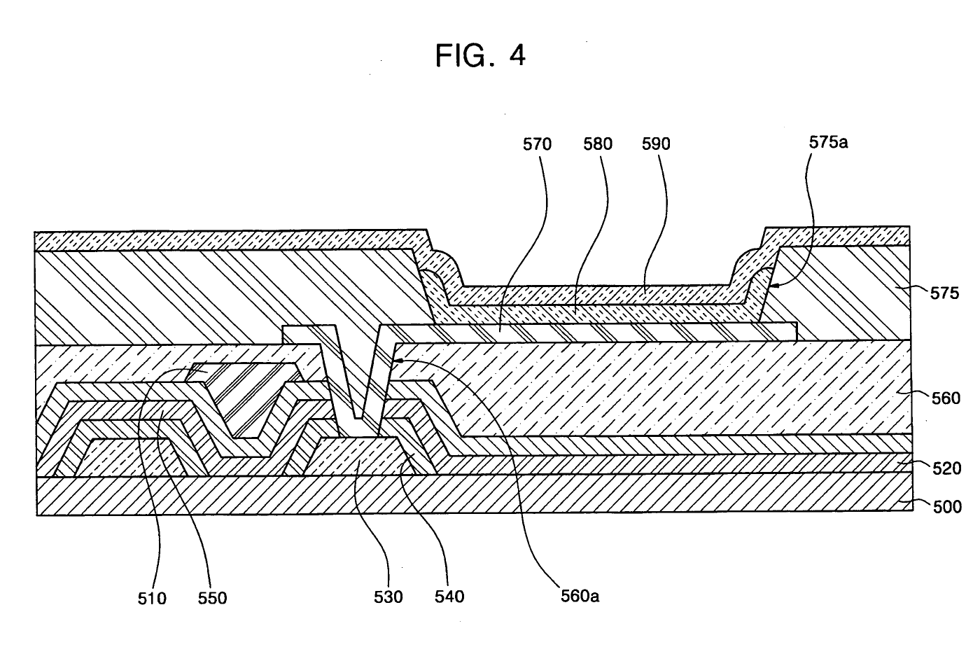

According to still another exemplary embodiment of the present invention, a display device, e.g., an organic light emitting display device, may be formed to include the OTFT described previously with respect to FIG. 2. The display device may include, as illustrated in FIG. 4, an OTFT, a passivation layer 560 on the OTFT, a pixel defining layer 575, first and second electrodes 570 and 590 on the passivation layer 560, and a light emitting layer 480 between the first and second electrodes 570 and 590. The OTFT may include a substrate 500, a gate electrode 510, a gate insulating layer 520, source/drain electrodes 530, a mixed layer 540, and an organic semiconductor layer 550. The display device in FIG. 4 may be similar to the display device described previously with respect FIG. 3, with the exception of including the OTFT described previously with respect to FIG. 2. Accordingly, detailed description of the OTFT respective elements will not be repeated herein. In this respect, it should be noted that first digits of reference numerals, i.e., ‘3’ and ‘5’, are employed to distinguish embodiments and not elements, and therefore, reference numerals having identical last two digits refer to similar elements.

According to embodiments of the present invention, a mixed layer of an organic material and a metal-containing material, i.e., a metal oxide or a metal salt, between an organic semiconductor layer and source/drain electrodes may reduce resistance therebetween, so that hole or electron mobility may be enhanced between an organic semiconductor layer and source/drain electrodes, thereby facilitating fabrication of a flat panel display device with improved image quality.

Exemplary embodiments of the present invention have been disclosed herein, and although specific terms are employed, they are used and are to be interpreted in a generic and descriptive sense only and not for purposes of limitation. Accordingly, it will be understood by those skilled in the art that various changes in form and details may be made without departing from the spirit or scope of the present invention as set forth in the following claims.

What is claimed is:

1. An organic thin film transistor (OTFT), comprising:
a substrate;
a gate electrode disposed on the substrate;
a gate insulating layer disposed on the entire surface of the substrate including the gate electrode;
source and drain electrodes spaced apart from each other on some regions of the gate insulating layer;
a mixed layer disposed on the source and drain electrodes and including an organic material and a metal oxide; and
a P-type organic semiconductor layer disposed on the substrate including the mixed layer.

2. The OTFT according to claim 1, wherein the organic material includes a material containing triarylamine or an acene-based material.

3. The OTFT according to claim 1, wherein the metal oxide is molybdenum oxide (MoO₃), vanadium oxide (V₂O₅), tungsten oxide (WO₃), or nickel oxide (NiO).

4. The OTFT according to claim 1, wherein the mixed layer has a thickness of about 10 Å to about 1000 Å.

5. The OTFT according to claim 1, wherein the mixed layer contains about 25 wt % to about 80 wt % metal oxide based on a total weight of the mixed layer.

6. The OTFT according to claim 2, wherein the acene-based material is one of anthracene, tetracene, pentacene, perylene, and coronene.

7. An organic thin film transistor (OTFT), comprising:
a substrate;
a gate electrode disposed on the substrate;
a gate insulating layer disposed on the entire surface of the substrate including the gate electrode;
source and drain electrodes spaced apart from each other on some regions of the gate insulating layer;
a mixed layer disposed on the source and drain electrodes and including an organic material and a metal salt; and
an N-type organic semiconductor layer disposed on the substrate including the mixed layer.

8. The OTFT according to claim 7, wherein the organic material comprises a material selected from the group consisting of acene, fully fluorinated acene, partially fluorinated acene, partially fluorinated oligothiophene, fullerene, fullerene having substituent, fully fluorinated phthalocyanine, partially fluorinated phthalocyanine, perylene tetracarboxylic diimide, perylene tetracarboxylic dianhydride, naphthalene tetracarboxylic diimide, and naphthalene tetracarboxylic dianhydride.

9. The OTFT according to claim 7, wherein the metal salt contains an alkali metal or an alkaline-earth metal.

10. The OTFT according to claim 7, wherein the mixed layer has a thickness of about 10 angstroms to about 1000 angstroms.

11. The OTFT according to claim 7, wherein the mixed layer contains about 5 wt % to about 50 wt % metal salt based on a total weight of the mixed layer.

12. The OTFT according to claim 8, wherein the acene-based material is one of anthracene, tetracene, pentacene, perylene, and coronene.

13. The OTFT according to claim 9, wherein the metal salt is cesium chloride (CsCl), cesium fluoride (CsF), or cesium carbonate (Cs₂CO₃).

14. A light emitting display device, comprising:
a substrate;
a gate electrode disposed on the substrate;
a gate insulating layer disposed on the entire surface of the substrate including the gate electrode;
source and drain electrodes spaced apart from each other on some regions of the gate insulating layer;
a mixed layer disposed on the source and drain electrodes, and including an organic material and a metal oxide;
a P-type organic semiconductor layer disposed on the substrate including the mixed layer;
a passivation layer disposed on the P-type organic semiconductor layer;
a first electrode connected to the source and drain electrodes;
a pixel defining layer exposing a portion of the first electrode;
an organic layer disposed on the first electrode, and including an organic emitting layer; and
a second electrode disposed on the organic layer.

15. The light emitting display device according to claim 14, wherein the organic material includes a material containing triarylamine or an acene-based material.

16. The light emitting display device according to claim 14, wherein the metal oxide is molybdenum oxide (MoO₃), vanadium oxide (V₂O₅), tungsten oxide (WO₃), or nickel oxide (NiO).

17. The light emitting display device according to claim 14, wherein the mixed layer has a thickness of about 10 angstroms to about 1000 angstroms.

18. The light emitting display device according to claim 14, wherein the mixed layer contains about 25 wt % to about 80 wt % metal oxide based on a total weight of the mixed layer.

19. A light emitting display device, comprising:
a substrate;
a gate electrode disposed on the substrate;
a gate insulating layer disposed on the entire surface of the substrate including the gate electrode;
source and drain electrodes spaced apart from each other on some regions of the gate insulating layer;
a mixed layer disposed on the source and drain electrodes, and including an organic material and a metal salt;
an N-type organic semiconductor layer disposed on the substrate including the mixed layer;
a passivation layer disposed on the N-type organic semiconductor layer;
a first electrode connected to the source and drain electrodes;
a pixel defining layer exposing a portion of the first electrode;
an organic layer disposed on the first electrode, and including an organic emitting layer; and
a second electrode disposed on the organic layer.

20. The light emitting display device according to claim 19, wherein the organic material comprises a material selected from the group consisting of acene, fully fluorinated acene, partially fluorinated acene, partially fluorinated oligothiophene, fullerene, fullerene having substituent, fully fluorinated phthalocyanine, partially fluorinated phthalocyanine, perylene tetracarboxylic diimide, perylene tetracarboxylic dianhydride, naphthalene tetracarboxylic diimide, and naphthalene tetracarboxylic dianhydride.

21. The light emitting display device according to claim 19, wherein the metal salt contains an alkali metal or an alkaline-earth metal.

22. The light emitting display device according to claim 19, wherein the mixed layer has a thickness of about 10 angstroms to about 1000 angstroms.

23. The light emitting display device according to claim 19, wherein the mixed layer contains about 5 wt % to about 50 wt % metal salt based on a total weight of the mixed layer.

24. The light emitting display device according to claim 21, wherein the metal salt is cesium chloride (CsCl), cesium fluoride (CsF), or cesium carbonate (Cs₂CO₃).
